(19) United States
(12) Patent Application Publication
(10) Pub. No.: US 2016/0137088 A1
(43) Pub. Date: May 19, 2016

(54) IBS APPARATUS HAVING A CLAMP AND CABLE CONNECTION PART INTEGRATED THEREIN

(71) Applicant: HYUNDAI MOBIS CO., LTD., Seoul (KR)

(72) Inventors: Yong Ho LIM, Suwon-si (KR); Yong CHUN, Suwon-si (KR); Kee Yang LEE, Hwaseong-si (KR); Seok Jong YU, Seoul (KR); Tae Sun CHO, Yongin-si (KR)

(21) Appl. No.: 14/830,648

(22) Filed: Aug. 19, 2015

(30) Foreign Application Priority Data
Nov. 19, 2014 (KR) 10-2014-0161867

(51) Int. Cl. B60L 11/18; G01R 31/36

(52) U.S. Cl. CPC B60L 11/1851; G01R 31/3696; G01R 31/3655

(57) ABSTRACT

An IBS (Intelligent Battery Sensor) apparatus having a clamp and cable connection part integrated therein may include: a clamp member comprising a clamp body to which a terminal of a battery is inserted; a coupling member to which a cable is coupled; a connection member having both ends to which the clamp member and the coupling member are coupled; and a sensor member coupled to the connection member and measuring a voltage value applied to the connection member. The clamp body, the coupling member, and the connection member may be integrated.

### CROSS-REFERENCES TO RELATED APPLICATIONS

The present application claims priority to Korean application number 10-2014-0161867, filed on Nov. 19, 2014, which is incorporated by reference in its entirety.

### BACKGROUND

The present disclosure relates to an IBS (Intelligent Battery Sensor) apparatus.

In general, a battery of a vehicle is arranged in an engine room, and supplies overall power required for the vehicle. According to the recent trend, various electronic parts such as a navigation system, an AV device, and a camera have been provided in addition to a starting device and a lighting device of the vehicle. Thus, it is becoming more important to manage the battery which supplies power to such devices. Therefore, an IBS apparatus is mounted to manage the state of charge, the deterioration degree, the restarting ability, and the temperature of the battery.

The related technology is disclosed in Korean Patent Laid-open Publication No. 10-2012-0038286 published on Apr. 23, 2012 and entitled “Battery sensor module”.

### SUMMARY

Embodiments of the present invention are directed to an IBS apparatus having a clamp and cable connection part integrated therein, which is capable of simplifying a manufacturing process, reducing a measurement error depending on a temperature change, and improving durability for vibration of a vehicle.

In one embodiment, an IBS apparatus having a clamp and cable connection part integrated therein may include: a clamp member including a clamp body to which a terminal of a battery is inserted; a coupling member to which a cable is coupled; a connection member having both ends to which the clamp member and the coupling member are coupled; and a sensor member coupled to the connection member and measuring a voltage value applied to the connection member. The clamp body, the coupling member, and the connection member may be integrated.

The clamp member may include: an opening formed through the clamp body so as to open one side of a terminal insertion hole to which the terminal is inserted; and a clamp control part coupled to both sides of the opening so as to control the width of the opening.

The clamp control part may be coupled to both sides of the opening, and expanded/contracted to control the width of the opening.

The clamp control part may include: a control bolt passing through control part insertion holes formed at both sides of the opening; and a control nut coupled to the control bolt while being in contact with one side of the opening, and controlling the width of the opening while the position at which the control nut is coupled to the control bolt is changed.

The control nut may be screw-coupled to the control bolt.

The coupling member may include: a coupling member body coupled to the connection member; and a coupling terminal part formed on the coupling member body and coupled to the cable.

The coupling terminal part may protrude from both sides of the coupling member body, have a shape surrounding the cable, and be coupled to the cable.

The coupling terminal part may be grounded to a vehicle body through the cable.

The coupling terminal part may have an uneven surface formed on the surface to which the cable is coupled, and the uneven surface may increase friction with the cable.

The connection member may include: a connection member body having both ends coupled to the clamp member and the connection member, respectively, electrically connecting the clamp member and the coupling member, and coupled to both ends of the sensor member; and a connection member groove concavely formed in the coupling member body, and positioned between both ends of the sensor member.

The clamp body, the coupling member, and the connection member may include a manganese alloy.

The IBS apparatus may further include a control member configured to calculate a current value flowing through the connection member based on the voltage value measured by the sensor member and a previously stored resistance value of the connection member.

### BRIEF DESCRIPTION OF THE DRAWINGS

FIG. 1 is a perspective view illustrating a state in which an IBS apparatus having a clamp and cable connection part integrated therein in accordance with an embodiment of the present invention is mounted.

FIG. 2 is a diagram illustrating the structure of the IBS apparatus having a clamp and cable connection part integrated therein in accordance with the embodiment of the present invention.

FIG. 3 is an expanded view illustrating a portion A of FIG. 1.

FIG. 4 is an expanded view illustrating a portion B of FIG. 2.

FIG. 5 is a schematic perspective view of an IBS apparatus having a clamp and cable connection part integrated therein in accordance with another embodiment of the present invention.

FIG. 6 is a schematic perspective view of an IBS apparatus having a clamp and cable connection part integrated therein in accordance with another embodiment of the present invention.

FIG. 7 is a schematic side view of the IBS apparatus having a clamp and cable connection part integrated therein in accordance with the embodiment of the present invention.

### DESCRIPTION OF EMBODIMENTS

Embodiments of the invention will hereinafter be described in detail with reference to the accompanying drawings. It should be noted that the drawings are not to precise scale and may be exaggerated in thickness of lines or sizes of components for descriptive convenience and clarity only.

Furthermore, the terms as used herein are defined by taking functions of the invention into account and can be changed according to the custom or intention of users or operators. Therefore, definition of the terms should be made according to the overall disclosures set forth herein.

When a typical IBS apparatus for a vehicle is manufactured, a shut resistor, a clamp, and a terminal are coupled through a complex process, and thus an assembly error may occur. Furthermore, the IBS apparatus may be easily damaged by an impact caused through vibration of the vehicle.

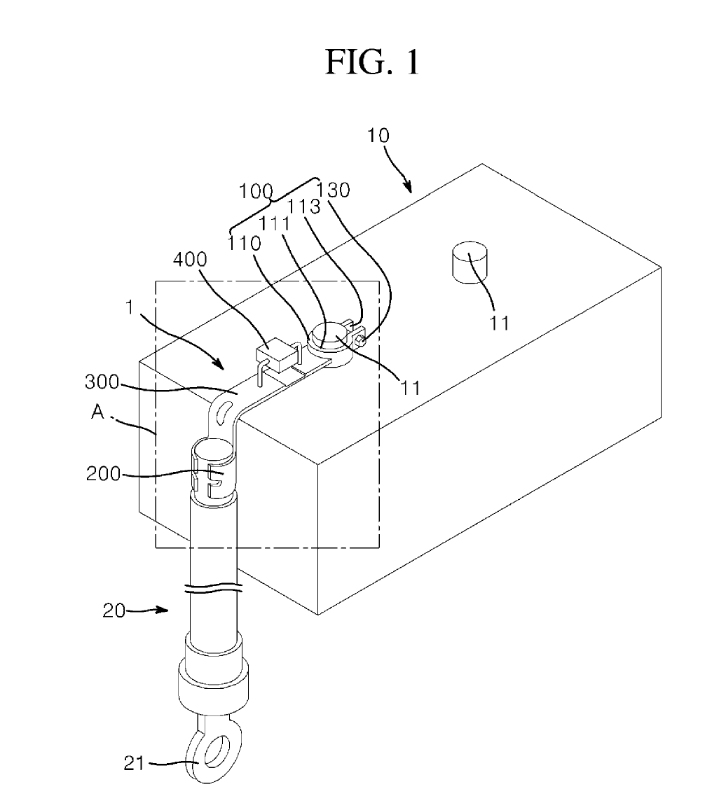

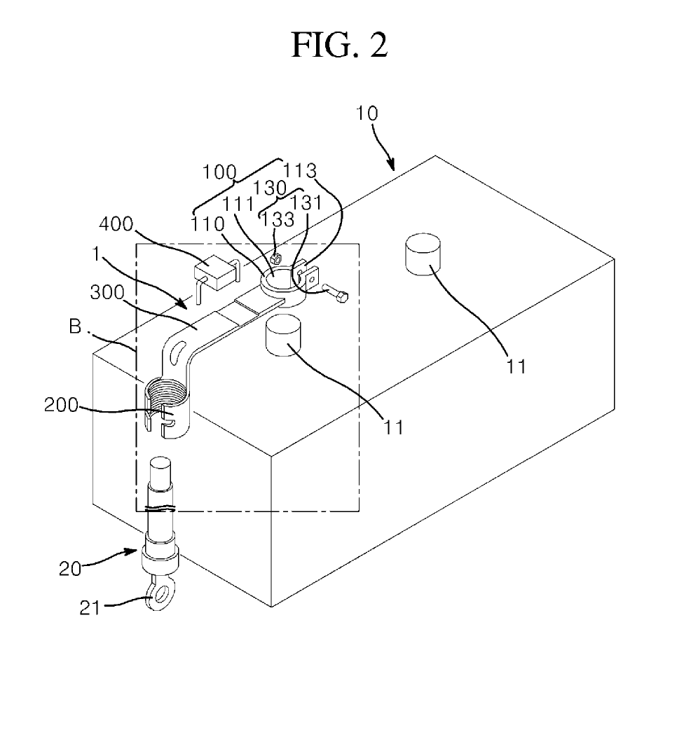

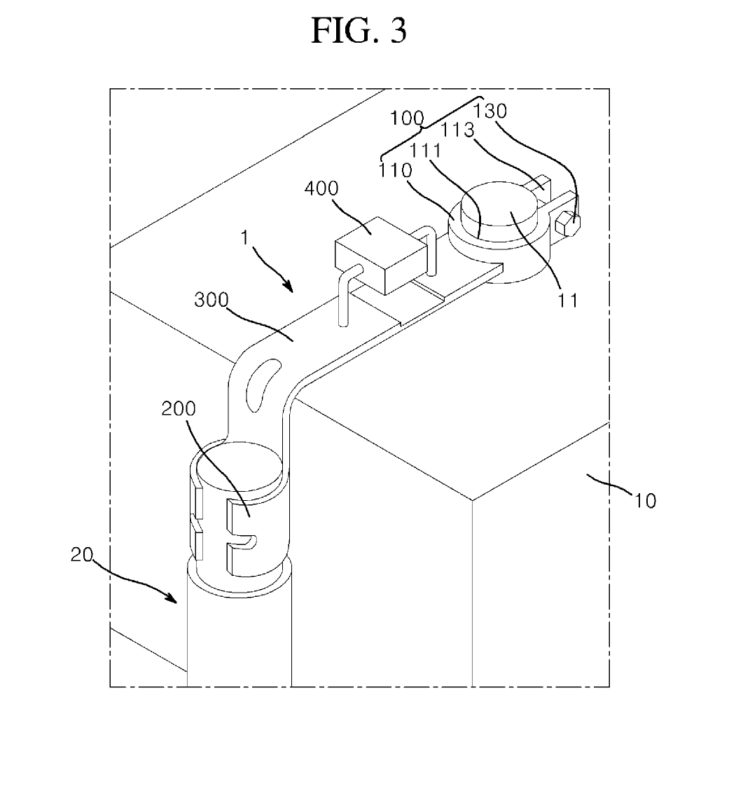

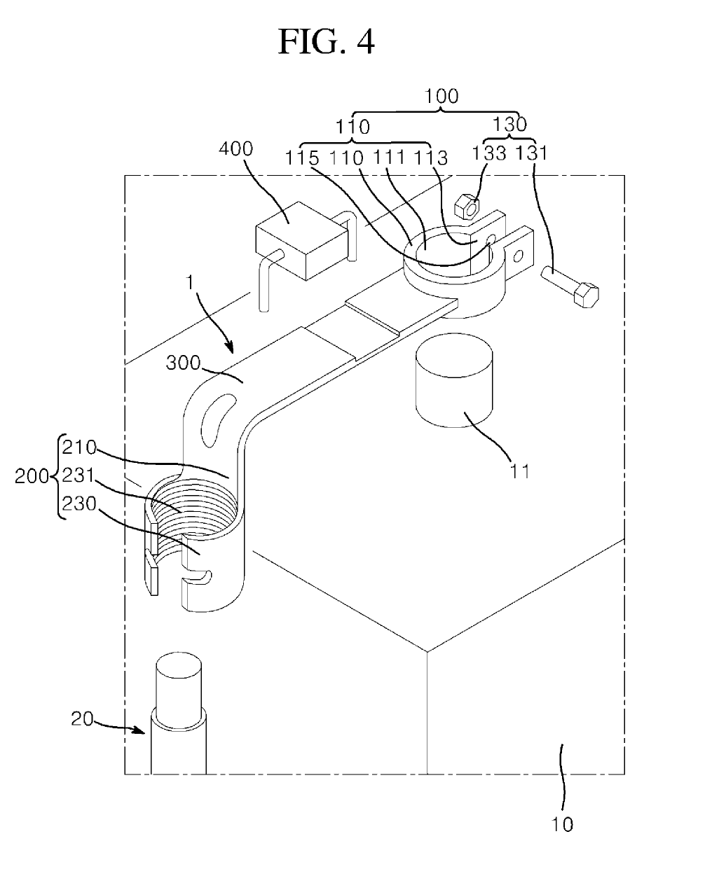

FIG. 1 is a perspective view illustrating a state in which an IBS apparatus having a clamp and cable connection part integrated therein in accordance with an embodiment of the present invention is mounted. FIG. 2 is a diagram illustrating the structure of the IBS apparatus having a clamp and cable connection part integrated therein in accordance with the embodiment of the present invention. FIG. 3 is an expanded view illustrating a portion A of FIG. 1. FIG. 4 is an expanded view illustrating a portion B of FIG. 2.

Referring to FIGS. 1 to 4, the IBS apparatus 1 having a clamp and cable connection part integrated therein in accordance with the embodiment of the present invention may include a clamp member 100, a coupling member 200, a connection member 300, and a sensor member 400, which are integrated therein. The IBS apparatus 1 may be mounted on a vehicle battery 10 and grounded to a vehicle body.

In the IBS apparatus 1 having a clamp and cable connection part integrated therein in accordance with the embodiment of the present invention, the clamp member 100, the coupling member 200, the connection member 300, and the sensor member 400 may be integrally formed. Thus, the numbers of parts and assembling processes can be reduced, and the durability of the apparatus can be improved.

The clamp member 100 may be coupled to a terminal 11 of the battery 10, or particularly a negative (−) terminal 11. In the present embodiment, the clamp member 100 may include a clamp body 110, an opening 113, and a clamp control part 130.

The clamp body 110 may be formed in a substantially cylindrical shape, and have a terminal insertion hole 111 formed therethrough in a vertical direction. The terminal 11 of the battery 10 may be inserted into the terminal insertion hole 111.

The opening 113 may be formed through a side surface of the clamp body 110, and open one side of the terminal insertion hole 111 while communicating the terminal insertion hole 111. The width of the opening 113 may be controlled by the clamp control part 130. When the width of the opening 113 is reduced, the cross-sectional area of the terminal insertion hole 111 may be reduced to pressurize the terminal 11 inserted into the terminal insertion hole 111. Then, the terminal 11 may be prevented from separating from the terminal insertion hole 111.

The clamp control part 130 may be coupled to both sides of the opening 113, and control the width of the opening 113 such that the terminal 11 is detachably coupled to the terminal insertion hole 111. In the present embodiment, the clamp control part 130 may include a control bolt 131 and a control nut 133.

The control bolt 131 and the control nut 133 may be coupled to each other through control part insertion holes 115 formed at both sides of the opening 113. According to the coupling strength between the control bolt 131 and the control nut 133, the width of the opening 113 may be controlled.

When the width of the opening 113 is reduced through an operation of the clamp control part 130, the coupling strength between the terminal 11 and the terminal insertion hole 111 may be increased while the cross-sectional area of the terminal insertion hole 111 decreases. Then, the terminal 11 may be coupled to the terminal insertion hole 111.

When the width of the opening 113 is increased through an operation of the clamp control part 130, the coupling strength between the terminal 11 and the terminal insertion hole 111 may be reduced while the cross-sectional area of the terminal insertion hole 111 increases. Then, the terminal 11 can be detached from the terminal insertion hole 111.

The coupling member 200 may be coupled to the cable 20 and grounded to the vehicle body through the cable 20. In the present embodiment, the coupling member 200 may include a coupling member body 210 and a coupling terminal part 230.

The coupling member body 210 may be coupled to the connection member 300. In the present embodiment, the coupling member body 210 may be integrated with the connection member 300, and electrically connect the connection member 300 and the cable 20.

The coupling terminal part 230 may be formed to protrude from both sides of the coupling member body 210. The coupling terminal part 230 may be formed in a shape surrounding the cable 20, and coupled to the cable 20. In the present embodiment, the coupling terminal part 230 may have an uneven surface 231 formed on the surface thereof, to which the cable 20 is coupled. The uneven surface 231 may increase friction with the cable 20, thereby preventing the cable 20 from separating from the coupling terminal part 230.

The connection member 300 may have both ends coupled to the clamp member 100 and the coupling member 200, and electrically connect the clamp member 100 and the coupling member 200. In the present embodiment, the connection member 300 may include a connection member body 310 and a connection member groove 330.

The connection member body 310 may have both ends coupled to the clamp member 100 and the coupling member 200, and include a manganese alloy to electrically connect the clamp member 100 and the coupling member 200. The connection member body 310 may be directly connected to the sensor member 400 to directly measure a voltage value.

In the present embodiment, the IBS apparatus 1 having a clamp and cable connection part integrated therein may be mounted on the engine room of the vehicle. When a manganese alloy is applied to the connection member body 310, the connection member body 310 can reduce an error of the voltage value measured through the sensor member 400 because the manganese alloy has a resistance value which slightly changes even though the temperature of the engine room is significantly changed.

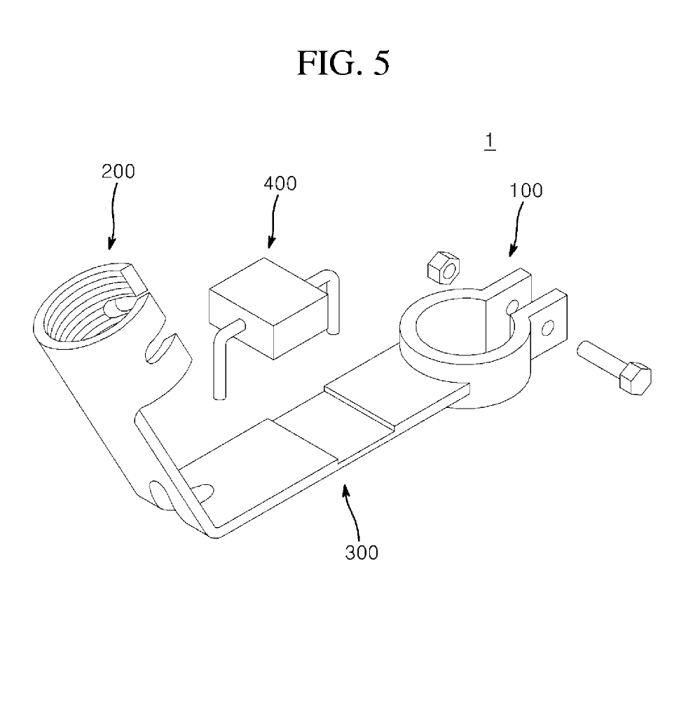

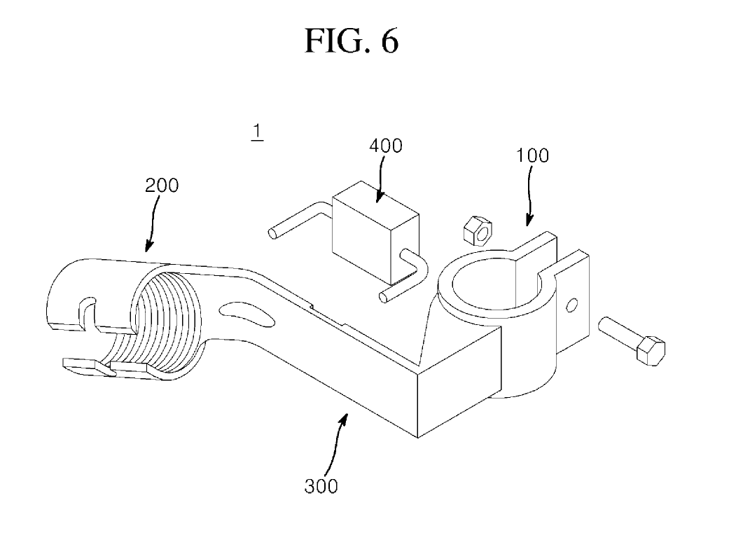

FIG. 5 is a schematic perspective view of an IBS apparatus having a clamp and cable connection part integrated therein in accordance with another embodiment of the present invention. FIG. 6 is a schematic perspective view of an IBS apparatus having a clamp and cable connection part integrated therein in accordance with another embodiment of the present invention.

Referring to FIGS. 4 to 6, the connection member body 310 may be formed in various shapes depending on the relative position between the terminal 11 and the cable 20.

The connection member body 310 may be electrically connected to the sensor member 400, and the resistance value measured through the sensor member 400 may be changed depending on the cross-sectional area of the part coupled to the sensor member 400.

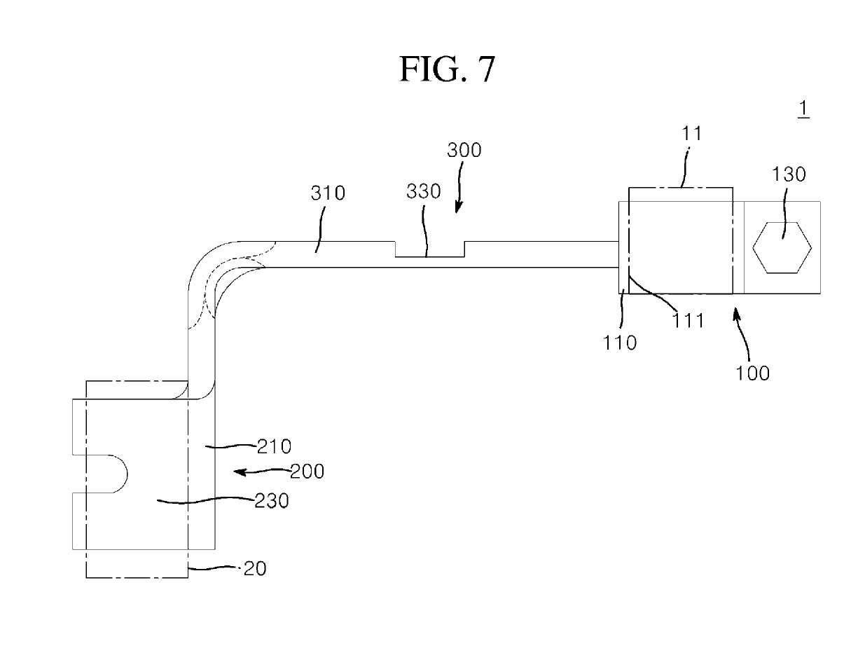

FIG. 7 is a schematic side view of the IBS apparatus having a clamp and cable connection part integrated therein in accordance with the embodiment of the present invention. Referring to FIG. 7, the cross-sectional area of the connection member 300 at the part connected to the sensor member 400 may be adjusted through the depth of the connection member groove 330 which is concavely formed in the connection member body 310 or the width of the connection member groove 330 or the connection member body 310.

The sensor member 400 may be coupled to the connection member 300, and measure a voltage value applied to the connection member 300. The voltage value measured through the sensor member 400 may be transmitted to a control member to which a resistance value of the part measured by the sensor member 400 is previously inputted. The control member may calculate a current value flowing through the connection member 300, based on the voltage value.

In the present embodiment, the clamp body 110, the coupling member 200, or the connection member 300 may include a manganese alloy. Since the manganese alloy corresponds to a material of which the resistance value is slightly changed with the temperature, the manganese alloy can reduce a variation of the resistance value even though the temperature of the engine room on which the IBS apparatus 1 is mounted is changed.

Hereafter, the operation principle and effect of the IBS apparatus having a clamp and cable connection part integrated therein in accordance with the embodiment of the present invention will be described as follows.

First, the screw coupling between the control bolt 131 and the control nut 133 may be loosened to expand the opening 113, and the terminal 11 of the battery 10 may be inserted into the terminal insertion hole 111.

When the terminal 11 is inserted into the terminal insertion hole 111, the control bolt 131 or the control nut 133 may be rotated to reduce the width of the opening 113. Then, the shape of the terminal insertion hole 111 may be changed to increase the coupling strength between the terminal 11 and the terminal insertion hole 111.

The cable 20 may be coupled to the coupling member 200. The coupling terminal part 230 may be pressurized toward the cable 20 through a tool so as to over the cable 20 in a state where an end of the cable 20 is in contact with the coupling member body 210. Then, the cable 20 may be fixed to the inside of the coupling terminal part 230 and the coupling member body 210.

The cable connection part 21 provided at the other end of the cable 20 may be coupled and grounded to the vehicle body through bolting or the like.

In a state where the clamp member 100 and the coupling member 200 are coupled to the terminal 11 and the vehicle, respectively, the sensor member 400 coupled to the connection member 300 may measure a voltage value flowing between the terminal 11 and the vehicle body, and transmit the measured voltage value to the control member.

The control member may measure the state of the battery 10 by calculating a current value flowing through the connection member 300, based on the measured voltage value and the resistance value of the connection member 300, which is previously inputted. The state of the battery 10 may indicate the state of charge, the deterioration degree, and the restarting ability of the battery 10.

Thus, in the IBS apparatus 1 having a clamp and cable connection part integrated therein in accordance with the embodiment of the present invention, the clamp body 110, the coupling member 200, and the connection member 300 can be integrated, a shut resistor can be omitted to reduce the number of assembly processes, an assembly error during an assembly process can be prevented, and the durability of the apparatus can be improved.

Furthermore, since the IBS apparatus 1 includes a manganese alloy of which the resistance value is slightly changed according to a temperature change, the IBS apparatus 1 can reduce a measurement error of the voltage value.

Although embodiments of the invention have been disclosed for illustrative purposes, those skilled in the art will appreciate that various modifications, additions and substitutions are possible, without departing from the scope and spirit of the invention as defined in the accompanying claims.

What is claimed is:

1. An IBS (Intelligent Battery Sensor) apparatus having a clamp and cable connection part integrated therein, comprising:
a clamp member comprising a clamp body to which a terminal of a battery is inserted;
a coupling member to which a cable is coupled;
a connection member having both ends to which the clamp member and the coupling member are coupled; and
a sensor member coupled to the connection member and measuring a voltage value applied to the connection member,
wherein the clamp body, the coupling member, and the connection member are integrated.

2. The IBS apparatus of claim 1, wherein the clamp member comprises:
an opening formed through the clamp body so as to open one side of a terminal insertion hole to which the terminal is inserted; and
a clamp control part coupled to both sides of the opening so as to control the width of the opening.

3. The IBS apparatus of claim 2, wherein the clamp control part is coupled to both sides of the opening, and expanded/contracted to control the width of the opening.

4. The IBS apparatus of claim 2, wherein the clamp control part comprises:
a control bolt passing through control part insertion holes formed at both sides of the opening; and
a control nut coupled to the control bolt while being in contact with one side of the opening, and controlling the width of the opening while the position at which the control nut is coupled to the control bolt is changed.

5. The IBS apparatus of claim 4, wherein the control nut is screw-coupled to the control bolt.

6. The IBS apparatus of claim 1, wherein the coupling member comprises:
a coupling member body coupled to the connection member; and
a coupling terminal part formed on the coupling member body and coupled to the cable.

7. The IBS apparatus of claim 6, wherein the coupling terminal part protrudes from both sides of the coupling member body, has a shape surrounding the cable, and is coupled to the cable.

8. The IBS apparatus of claim 6, wherein the coupling terminal part is grounded to a vehicle body through the cable.

9. The IBS apparatus of claim 6, wherein the coupling terminal part has an uneven surface formed on the surface to which the cable is coupled, and the uneven surface increases friction with the cable.

10. The IBS apparatus of claim 1, wherein the connection member comprises:
a connection member body having both ends coupled to the clamp member and the connection member, respectively, electrically connecting the clamp member and the coupling member, and coupled to both ends of the sensor member; and
a connection member groove concavely formed in the coupling member body, and positioned between both ends of the sensor member.

11. The IBS apparatus of claim 1, wherein the clamp body, the coupling member, and the connection member comprise a manganese alloy.

12. The IBS apparatus of claim 11, further comprising a control member configured to calculate a current value flowing through the connection member based on the voltage value measured by the sensor member and a previously stored resistance value of the connection member.
